(19) United States
(12) Patent Application Publication
(10) Pub. No.: US 2016/0343930 A1
(43) Pub. Date: Nov. 24, 2016

(54) THERMOELECTRIC COMPOSITE MATERIAL AND METHOD FOR PRODUCING SAME

(71) Applicant: SK INNOVATION CO., LTD., Seoul (KR)

(72) Inventors: Jong-Soo RHYEE, Gyeonggi-do (KR); Min-Ho LEE, Gyeongsangnam-do (KR)

(21) Appl. No.: 15/162,343

(22) Filed: May 23, 2016

(30) Foreign Application Priority Data
May 22, 2015 (KR) 10-2015-0071999

(51) Int. Cl. H01L 35/32; H01L 35/34; H01L 35/16

(52) U.S. Cl. CPC H01L 35/32; H01L 35/16; H01L 35/34

(57) ABSTRACT

Disclosed is a thermoelectric composite material, comprising a Sb—Te-based matrix, and Ag—Te-based particles dispersed in the matrix phase, wherein an interface is formed between the matrix and the particles. Further, disclosed is a method for producing the thermoelectric composite material.

### CROSS-REFERENCE TO RELATED APPLICATIONS

This application claims the priority of Korean Patent Application No. KR 10-2015-0071999 filed on May 22, 2015, in the Korean Intellectual Property Office, the disclosure of which is incorporated herein by reference.

### BACKGROUND

1. Technical Field

The present invention relates to a thermoelectric composite material and a method for producing the same.

2. Description of the Related Art

In general, thermoelectric materials can be utilized in active cooling, waste heat power generation, and the like by using Peltier effect and Seebeck effect.

The Peltier effect occurs when a direct-current (DC) voltage is applied and holes of a p-type material and electrons of an n-type material are transported to allow for a heat generation and a heat absorption at both ends of the materials. The Seebeck effect occurs when heat is supplied from an external heat source and a current flow is generated through a material while electrons and holes are transported to generate a power.

Active cooling with these thermoelectric materials improves the thermal stability of devices, does not cause vibration and noise, and does not use a separate condenser and refrigerant. Therefore, the volume of these devices is small and the active cooling method is environmentally friendly. Thus, active cooling that uses such thermoelectric materials can be applied in refrigerant-free refrigerators, air conditioners, micro-cooling systems, and the like. In particular, when a thermoelectric device is attached to a memory device, the temperature of the device can be maintained in a uniform and stable state, as compared to conventional cooling methods. Thus, the memory devices can have improved performance.

In addition, when thermoelectric materials are used in thermoelectric power generation using the Seebeck effect, waste heat can be used as an energy source. Thus, thermoelectric materials can be applied in a variety of fields that increase energy efficiency or reuse waste heat, such as in vehicle engines and air exhausts, waste incinerators, waste heat in iron mills, power sources of medical devices in the human body powered using human body heat, and the like.

As a factor of determining the performance of such thermoelectric materials, a dimensionless performance index ZT defined as Equation 1 below is used:

$$ZT = \frac{{S}^{2} σ T}{k} \qquad ( 1 )$$

where S is a Seebeck coefficient, σ is an electrical conductivity, T is an absolute temperature, and κ is a thermal conductivity.

To increase the performance of such thermoelectric materials, the values of the dimensionless performance index ZT should increase. Accordingly, there is a need to develop a material having a high Seebeck coefficient and electrical conductivity and low thermal conductivity.

It has been known in the art that if a low dimensional nanostructure is prepared by a process for implementing a high ZT value, the Seebeck coefficient is increased by a quantum confinement effect, and if an energy barrier having a thickness shorter than the mean free path of electrons and longer than the mean free path of phonons is formed in a thermoelectric semiconductor, since an electricity is passed therethrough and a heat is blocked, ZT values are increased.

### SUMMARY

The present disclosure provides a thermoelectric composite material having a high Seebeck coefficient and electrical conductivity and very low thermal conductivity, and a process for producing the same.

According to an aspect of the present disclosure, there is provided a thermoelectric composite material including a Sb—Te-based matrix, and Ag—Te-based particles dispersed in the matrix phase, wherein an interface is formed between the matrix and the particles.

Sb in the matrix may be doped with at least one element selected from the group consisting of Te, Sn and Pb, or Te in the matrix may be doped with at least one element selected from the group consisting of Se, S, I, Br and Cl.

Ag in the particles may be doped with at least one element selected from the group consisting of Zn, Cu, Ni, Co, Fe, Cd, Pd, Rh, Ru, Au and Pt, or Te in the particles may be doped with at least one element selected from the group consisting of Se, S, I, Br and Cl.

The particles may have a melting point in the range of 600 to 1,000° C.

The particles may have a diameter in the range of 20 nm to 2 μm.

The particles may be conglomerated to form a cluster, or the particles may be each in discrete form.

The weight ratio of the matrix to the particle may be 1:1 to 20:1.

The thermoelectric material may be a bulk phase.

The thermoelectric material may have a Seebeck coefficient of 120 μV/K or more at 700K.

The thermoelectric material may have an electric conductivity of 500 S/cm or more.

The thermoelectric material may have a thermal conductivity of 1.8 W/mK or less.

The thermoelectric material may have a density corresponding to 70% to 100% of the theoretical density.

According to another aspect of the present disclosure, there is provided a method for producing the thermoelectric composite material, including mixing a Sb—Te-based compound and an Ag—Te-based compound; and precipitating the Ag—Te-based compound from the mixture.

According to a still another aspect of the present disclosure, there is provided a method for producing the thermoelectric composite material, including melting a raw material comprising Sb, Ag and Te elements, and inducing a phase separation of the melt.

As mentioned above, the thermoelectric composite material according to the present disclosure includes a Sb—Te-based matrix, and Ag—Te-based particles dispersed in the matrix phase, wherein an interface is formed between the matrix and the particles, such that the thermoelectric composite can have a high Seebeck coefficient and electrical conductivity and very low thermal conductivity, and thus produce a better performance index. Therefore, the thermoelectric composite material may be suited for use in refrigerant-free refrigerators, air conditioners, waste heat power generation, thermoelectric nuclear power generation for military and aerospace, micro-cooling system, and the like.

### BRIEF DESCRIPTION OF DRAWINGS

The above and other objects and features of the present invention will become apparent from the following description of the disclosure, when taken in conjunction with the accompanying drawings, in which:

FIG. 1 is a graph showing the results of X-ray diffraction for Sb₂Te₃ compound, Ag₂Te compound, and thermoelectric composite materials according to Examples 1 and 4.

FIG. 2(a), 2(b) are a photograph showing a scanning electron microscope (SEM) in cross-section ((a) press-sintering direction and (b) press-sintering vertical direction) of the thermoelectric composite material according to Example 1.

FIG. 3(a) to 3(d) show electron microscopic images for an interface in the thermoelectric composite material according to Example 1 ((a) 5,000 times magnification and (b) 20,000 times magnification), and graphs showing an energy dispersive X-ray spectroscopy of a composition for the thermoelectric composite material according to Example 1 ((c) Ag₂Te part indicated by red square in (a) and Sb₂Te₃ part indicated by dark area in (b)).

FIG. 4 is a graph showing a Seebeck coefficient versus temperatures of the thermoelectric composite material according to Examples 1 to 6.

FIG. 5 is a graph showing an electrical conductivity versus temperatures of the thermoelectric composite material according to Examples 1 to 6.

FIG. 6 is a graph showing a thermal conductivity versus temperatures of the thermoelectric composite material according to Examples 1 to 6.

FIG. 7 is a graph showing a lattice thermal conductivity versus temperatures of the thermoelectric composite material according to Examples 1 to 6.

FIG. 8 is a graph showing a power factor (S²σ) versus temperatures of the thermoelectric composite material according to Examples 1 to 6.

FIG. 9 is a graph showing a dimensionless performance index (ZT) value versus temperatures of the thermoelectric composite material according to Examples 1 to 6.

### DETAILED DESCRIPTION

Hereinafter, embodiments of the present disclosure will be described in detail with reference to the accompanying drawings. It should be understood that the present disclosure is not limited to the following embodiments, and that the embodiments are provided for illustrative purposes only. The scope of the disclosure should be defined only by the accompanying claims and equivalents thereof.

Researches on Sb—Te-based compounds such as Sb₂Te₃ as a thermoelectric material have already been made. Sb₂Te₃ itself does not have a high performance index. However, when Sb₂Te₃ is reacted with Bi₂Te₃ to form Bi_{0.5}Sb_{1.5}Te₃ compound, as a typical p-type thermoelectric material, it has a dimensionless performance index (ZT) value of about 1.0 at room temperature. In addition, there also has been made researches on Ag—Te-based compounds such as Ag₂Te as a conventional thermoelectric material. Ag₂Te has a dimensionless performance index value of about 0.64 at 575 K. These single compounds have limited increase in performance index due to intrinsic properties of the materials.

Further, Sb₂Te₃ and Ag₂Te are known as a topological insulator. The topological insulator is a material having specific properties that behaves as a semiconductor or a non-conductor in its interior but whose surface has metallic properties.

The present disclosure is now intended to enhance the Seebeck coefficient and electric conductivity simultaneously by using bulk semiconductor properties and surface metallic properties through the formation of a composite of the topological insulator. The inventors have found that after preparing a thermoelectric composite material including a Sb—Te-based matrix, and Ag—Te-based particles dispersed in the matrix phase, wherein an interface is formed between the matrix and the particles, the prepared thermoelectric composite material can have a high Seebeck coefficient and electrical conductivity and very low thermal conductivity, and consequently have completed the present invention.

Hereinafter, the present invention will be described in detail.

The present disclosure provides a thermoelectric composite material including a Sb—Te-based matrix, and Ag—Te-based particles dispersed in the matrix phase, wherein an interface is formed between the matrix and the particles.

First, the thermoelectric composite material according to the present disclosure comprises a Sb—Te-based matrix.

The Sb—Te-based matrix may have a relatively high ZT value due to a low thermal conductivity of the Sb—Te-based compounds. Specifically, the Sb—Te-based matrix may be Sb₂Te₃.

In this embodiment, Sb in the matrix may be doped with at least one element selected from the group consisting of Te, Sn and Pb, or Te in the matrix may be doped with at least one element selected from the group consisting of Se, S, I, Br and Cl, thereby providing optimized current density. As a result, two-band conduction where electrons and holes coexist can occur. In this case, it can have only electron or hole conduction characteristics. This provides a thermoelectric material with a large power factor and a very low thermal conductivity.

For example, the dopant element may be added in the form of one component, two components, or three components. In the case of two components, they may be added in the molar ratio of 1:9 to 9:1. In the case of three components, they may be added in the molar ratio of 1:0.1-9.0:0.1-9.0. However, the present disclosure is not limited thereto.

Next, the thermoelectric material according to the present disclosure may include Ag—Te-based particles dispersed in the matrix phase.

The Ag—Te-based particles will have increased ZT values due to a high electrical conductivity and low thermal conductivity of the Ag—Te-based compounds. Specifically, the Ag—Te-based particles may be Ag₂Te.

In this embodiment, Ag in the particles may be doped with at least one element selected from the group consisting of Zn, Cu, Ni, Co, Fe, Cd, Pd, Rh, Ru, Au and Pt, or Te in the particles may be doped with at least one element selected from the group consisting of Se, S, I, Br and Cl, thereby providing an optimized current density. As a result, two-band conduction where electrons and holes coexist can occur. In this case, it can have only electron or hole conduction characteristic. This provides a thermoelectric material with a large power factor and a very low thermal conductivity.

For example, the dopant element may be added in the form of one component, two components, or three components. In the case of two components, they may be added in the molar ratio of 1:9 to 9:1. In the case of three components, they may be added in the molar ratio of 1:0.1-9.0:0.1-9.0. However, the present disclosure is not limited thereto.

The melting point of the particles may preferably be in the range of 600° C. to 1,000° C., but is not limited thereto. If the melting point of the particles is less than 600° C., the sintering temperature difference between the Sb—Te-based matrix and the dispersed particles is excessively increased, which therefore renders difficult to sinter. If the melting point of the particles exceeds 1,000° C., the elevated temperature makes it difficult to sinter, and the sintered density decreases at low temperature.

In addition, the diameter of the particles may preferably be in the range of 20 nm to 2 μm, but is not limited to thereto. If the diameter of the particles is less than 20 nm, it is difficult to prepare the particles. If the diameter of the particles exceeds 2 μm, the increasing effect of ZT values is reduced in preparing a thermoelectric composite material.

Specifically, the particles may be united to form a cluster, or the particles may each be present in discrete form. In particular, if the particles are distributed in discrete form, it is more preferable than what is present as a cluster in terms of reducing the thermal conductivity and independently controlling the physical properties.

Since an interface between the matrix and the particles are formed, the thermal conductivity can be lowered by a phonon scattering at the interface.

The particles are evenly distributed in the matrix phase, and maintain a precipitated state or a phase separated state, such that the interface between the matrix and the particles can be formed.

The weight ratio of the matrix and the particle may be in the range of 1:1 to 20:1, preferably 5:1, and more preferably 1:1 to 3:1. If the weight ratio of the matrix and the particles is below the above range, the electric conductivity may be decreased. If the weight ratio of the matrix and the particles exceeds the above range, the Seebeck coefficient may be decreased.

The thermoelectric material may be a bulk phase. When the thermoelectric material is a bulk phase, the manufacturing process is easy and inexpensive, thereby providing high process efficiency. Further, both the application to a large area and the control of a crystal size may be easily made to give a high availability of the material.

The thermoelectric material may have a Seebeck coefficient of 120 μV/K or more at 700K, preferably 150 μV/K or more at 700K. When the thermoelectric material has a Seebeck coefficient greater than 120 μV/K at 700K, the optimum power factor regions can be obtained. At this time, in order for the thermoelectric material to have a Seebeck coefficient greater than 150 μV/K at 700K, the weight ratio of the matrix and the particles should be maintained between 1:1 and 5:1.

In general, low dimensional conductivity is known to increase a higher energy state density at Fermi level. Sharp changes in the energy state density will increase a Seebeck coefficient, as shown in equation 2 below:

$$S ∼ \frac{{d}^{2} ln ɛ}{{dk}^{2}} {\vert}_{ɛ = {E}_{F}} \qquad ( 3 )$$

where S is a Seebeck coefficient, a is an energy, E_{F} is a Fermi energy.

The thermoelectric material has a low dimensional electrical characteristic within its lattice structure. As a result, the energy state density becomes higher at Fermi level, and a higher Seebeck coefficient will be obtained at such high energy state density.

The thermoelectric material shows a low thermal conductivity while having increased Seebeck coefficient due to the low dimensional conductivity characteristic. Therefore, it satisfies the characteristics required as a thermoelectric material.

Further, the thermoelectric material may have an electrical conductivity of 500 S/cm or more at 700K. When the thermoelectric material has an electrical conductivity of 500 S/cm or more at 700K, the optimum power factor regions can be obtained.

Additionally, the thermoelectric material may have a thermal conductivity of 1.8 W/mK or less at 700K, preferably a thermal conductivity of 1.0 W/mK or less at 700K, but is not limited thereto. When the thermoelectric material has a thermal conductivity of 1.8 W/mK or less at 700K, high ZT values can be obtained. At this time, in order for the thermoelectric material to have a thermal conductivity of less than or equal to 1.0 W/mK at 700K, the weight ratio of the matrix and the particles should be maintained between 1:1 and 5:1.

In general, thermal conductivity (kₜₒₜ) is a sum of a thermal conductivity caused by lattice vibration (kₚₕ) and a thermal conductivity caused by electrons (kₑₗ), as given by the equation kₜₒₜ=kₑₗ+kₚₕ, wherein since the former thermal conductivity is proportional to an electric conductivity (p) and temperature (T) by Wiedemann-Frantz principle, the former thermal conductivity is a dependent variable of an electric conductivity.

kₑₗ=LT/ρ (3)

where T is a temperature, ρ is an electrical conductivity, and L=2.44×10⁻⁸ ΩW/K², wherein K is an absolute temperature.

In addition, the thermoelectric material may have a density corresponding to 70% to 100% of the theoretical density. The thermoelectric material may have a density corresponding to 79% to 100% of the theoretical density, preferably 95% to 100% of the theoretical density by a densification process, but is not limited thereto. An ionic conductivity may be increased with the density of the thermoelectric material.

The densification process may include for example the following three methods:

(1) Hot press method: this method involves filling a powder compound into a mold having a predetermined shape, and press-sintering the compound at a high temperature, e.g., 300 to 800° C., and at a high pressure, e.g., 30 to 300 MPa;

(2) Spark plasma sintering method: this method involves sintering a powder compound in a short period of time by applying a high voltage current, e.g., about 50 to 500 amperes (A); and

(3) Hot forging method: this method involves extrusion-sintering a powder compound at a high temperature, e.g., about 300° C. to about 700° C., when the powder compound is press molded.

According to an embodiment of the present disclosure, a method for producing a thermoelectric composite material may include mixing a Sb—Te-based compound and an Ag—Te-based compound; and precipitating the Ag—Te-based compound from the mixture.

Specifically, the Sb—Te-based compound and Ag—Te-based compound are filled into an agate mortar or a planetary ball milling to make a powder, and then mixed in an organic solvent. After drying off the organic solvent, the Ag—Te-based compound is precipitated from the mixture.

After the step of precipitation, it may further include the step of performing the above-described densification process.

In this embodiment, the Sb—Te-based compound and the Ag—Te-based compound may have a polycrystalline or single crystal structure. Therefore, the synthesis method is classified into a polycrystalline synthesis method and a single crystal growth method.

The polycrystalline synthesis method may include ampoule method, arc melting method, solid state reaction method, etc. and will be briefly described as follows:

(1) Ampoule method: this method involves adding a material element to an ampoule made of a quartz tube or a metal, sealing the ampoule in a vacuum, and heat treating the ampoule;

(2) Arc melting method: this method involves adding a material element to a chamber, discharging an arc in an inert gas atmosphere to dissolve the material element, thereby resulting in the formation of a sample; and

(3) Solid state reaction method: this method involves mixing a powder material and then heat treating the resultant material, or heat treating the mixed powder, and then processing and sintering the resultant powder.

Next, the single crystal growth method may include metal flux method, Bridgeman method, etc. and will be briefly described as follows:

(1) Metal flux method: this method involves adding a material element and an element to a furnace, wherein the element provides an atmosphere so that the material element can grow satisfactorily into a crystal at a high temperature in the furnace, and heat treating the resultant material at a high temperature to grow into a crystal;

(2) Bridgeman method: this method involves adding a material element to a furnace, heating the material element at a high temperature until the material element is melted from an end portion of the furnace, and then slowly moving a hot region, such that the material element passes through the hot region to locally melt the material element to grow a crystal;

(3) Optical floating zone method: this method involves preparing a material element in the form of a seed rod and a feed rod, converging light of a lamp on the feed rod to locally melt the material element, and then slowly moving a melted region upwardly to melt the material element to grow a crystal; and

(4) Vapor transport method: this method involves placing a material element into a bottom portion of a quartz tube, heating the bottom portion containing the material element, and maintaining a top portion of the quartz tube at a low temperature to induce a solid state reaction at a low temperature while the material element is evaporated, thereby growing a crystal.

According to a still another embodiment of the present disclosure, a method for producing the thermoelectric composite material may include melting a raw material comprising Sb, Ag and Te elements, and inducing a phase separation of the melt.

Specifically, a raw material comprising Sb, Ag and Te elements is melted by a heat treatment. Then, the melt should not form a solid solution on phase diagram, and a phase separation is induced by cooling the melt at an appropriate temperature condition. The phase separation means that phases are separated without mixing due to a difference in miscibility of the phase diagram during cooling. A particular cooling condition of the phase separation is dependent upon the material and is determined through experimentation. For example, the phase separation may be accomplished with slow cooling or rapid cooling from a temperature of 500 to 600° C. which is in the range of between the melting temperature of Sb₂Te₃ and the melting temperature of Ag₂Te to a temperature of 100 to 300° C. which is a solid solution temperature.

After inducing the phase separation, it may further include the step of performing the above-described densification process.

Further, the present disclosure provides a thermoelectric module comprising a first electrode, a second electrode, and a thermoelectric device interposed between the first electrode and the second electrode, wherein the thermoelectric device is formed from the thermoelectric composite material.

The thermoelectric device may be formed by molding the thermoelectric material by cutting process, etc. The thermoelectric device is herein defined by p-type thermoelectric device. The thermoelectric device may be formed by molding the thermoelectric material to a predetermined shape such as a rectangular shape.

The thermoelectric device may be a device that can be combined with an electrode and produce a cooling effect by an applied current or generate a power by a temperature difference.

Further, the present disclosure provides a thermoelectric device including a thermoelectric module comprising a heat supply source, a thermoelectric device for absorbing heat from the heat supply source, a first electrode arranged in contact with the thermoelectric device, and a second electrode opposite the first electrode, the second electrode being arranged in contact with the thermoelectric device, wherein the thermoelectric device is formed from the thermoelectric composite material.

Accordingly, the thermoelectric composite material according to the present disclosure includes a Sb—Te-based matrix, and Ag—Te-based particles dispersed in the matrix phase, wherein an interface is formed between the matrix and the particles, such that the thermoelectric composite material can have a high Seebeck coefficient and electrical conductivity and very low thermal conductivity, and thus produce a better performance index. Therefore, the thermoelectric composite material may be suited for use in refrigerant-free refrigerators, air conditioners, waste heat power generation, thermoelectric nuclear power generation for military and aerospace, micro-cooling system, etc.

Hereinafter, the present disclosure will be described in more detail with reference to some preferred examples. However, it should be understood that the following examples are provided for illustrative purposes only and are not to be in any way construed as limiting the present disclosure.

### Examples

### Example 1

Each of elements Sb and Te was weighed based on the compositional ratio, and filled into a quartz tube, and then vacuum sealed. The mixture was allowed to melt at 800° C. for 24 hours, and then cooled slowly at a rate of 10° C./h to form Sb₂Te₃ compound.

Each of elements Ag and Te was weighed based on the compositional ratio, and transferred into a quartz tube, and then vacuum sealed. They were allowed to melt at 800° C. for 24 hours, and quenched with water at 500° C. to form Ag₂Te compound.

The Sb₂Te₃ compound and Ag₂Te compound were filled into an agate mortar to prepare a powder. Sb₂Te₃ powder and Ag₂Te powder were weighed in the weight ratio of 2:1 as shown in Table 1, and mixed in n-hexane. N-hexane was dried off to precipitate Ag₂Te powder. Then, the precipitate was transferred into a graphite mold, and press-sintered at a temperature of 400° C. and a pressure of 70 MPa for 1 hour, obtaining a thermoelectric composite material having a density corresponding to 95% of the theoretical density.

### Examples 2-6

Thermoelectric composite materials were prepared in a similar manner as in Example 1, except that Sb₂Te₃ powder and Ag₂Te powder were weighed in a weight ratio as shown in Table 1.

TABLE 1

| | Weight ratio of Sb₂Te₃ powder |
|---|---|
| | and Ag₂Te powder |
| Example 1 | 2:1 |
| Example 2 | 4:1 |
| Example 3 | 6:1 |
| Example 4 | 8:1 |
| Example 5 | 10:1 |
| Example 6 | 12:1 |

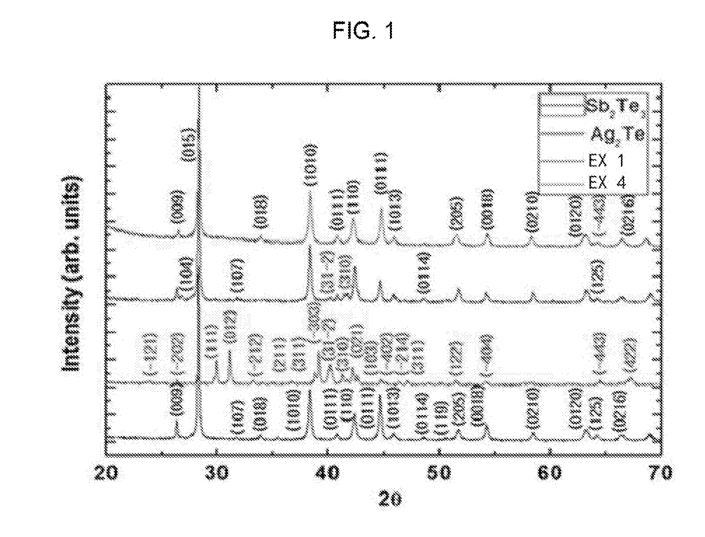

FIG. 1 is a graph showing the results of X-ray diffraction for Sb₂Te₃ compound, Ag₂Te compound, and thermoelectric composite materials according to Examples 1 and 4. Referring to FIG. 1, Sb₂Te₃ compound and Ag₂Te compound were observed in a single phase, and the thermoelectric composite materials according to Examples 1 and 4 were observed in a mixed phase, while impurities were not observed. That is, since no changes in lattice parameters were found between Sb₂Te₃ compound and Ag₂Te compound, and the thermoelectric composite material in Examples 1 to 4, it can be seen that in the thermoelectric composite material according to Examples 1 to 4, the Ag₂Te compound maintains a precipitated or phase separated state without subjecting to a solid solution treated in Sb₂Te₃ compound.

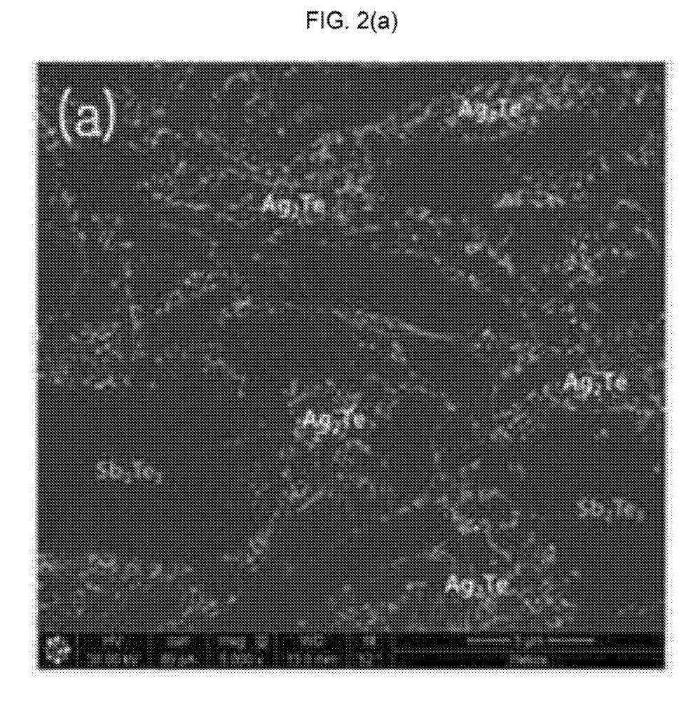

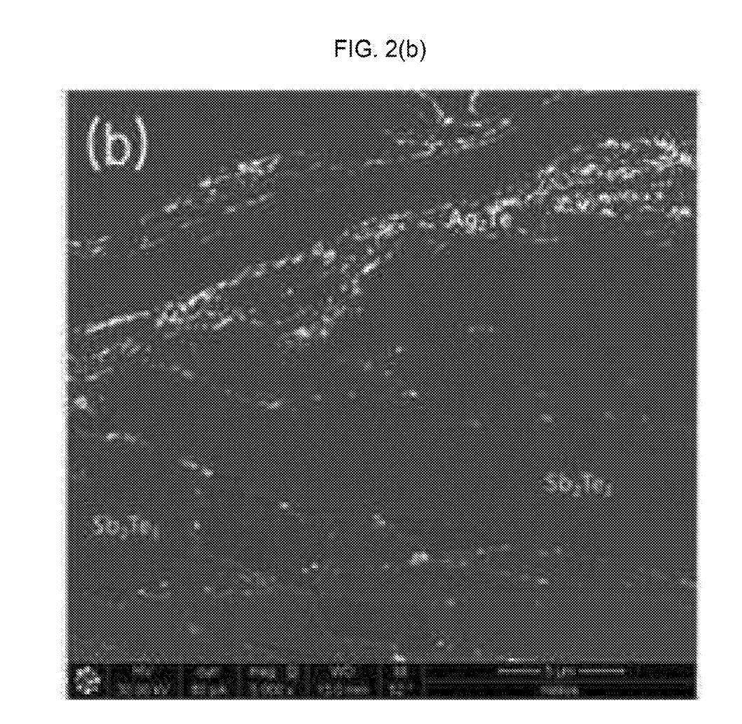

FIG. 2(a), 2(b) are a photograph showing a scanning electron microscope (SEM) in cross-section ((a) press-sintering direction and (b) press-sintering vertical direction) of the thermoelectric composite material according to Example 1. Referring to FIGS. 2(a) and 2(b), it was seen that in the thermoelectric composite material according to Example 1, Ag₂Te particles were evenly dispersed in Sb₂Te₃ matrix phase, and kept in precipitated or phase separated state. Further, it could be seen that Ag₂Te particles were predominantly distributed along the press-sintering vertical direction.

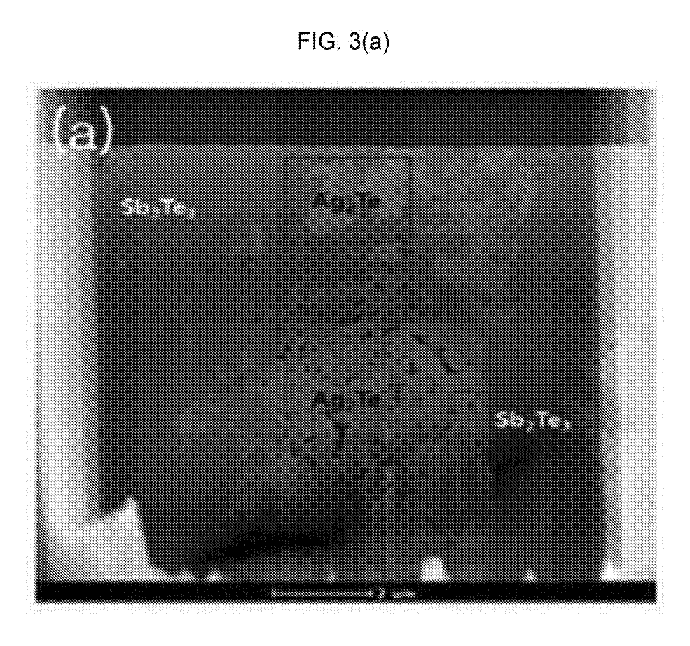

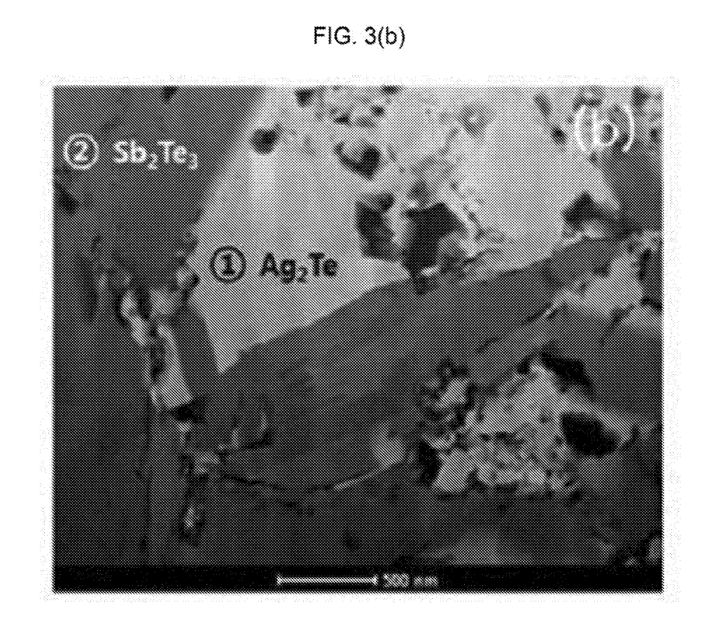

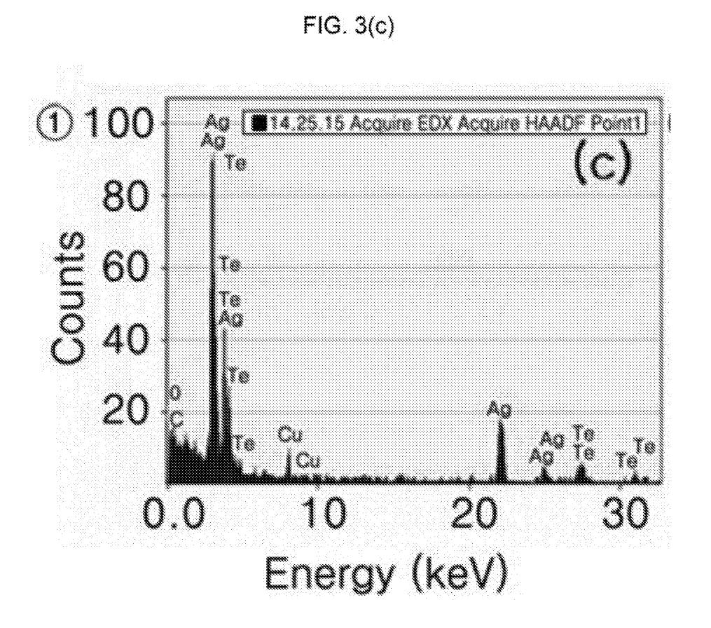

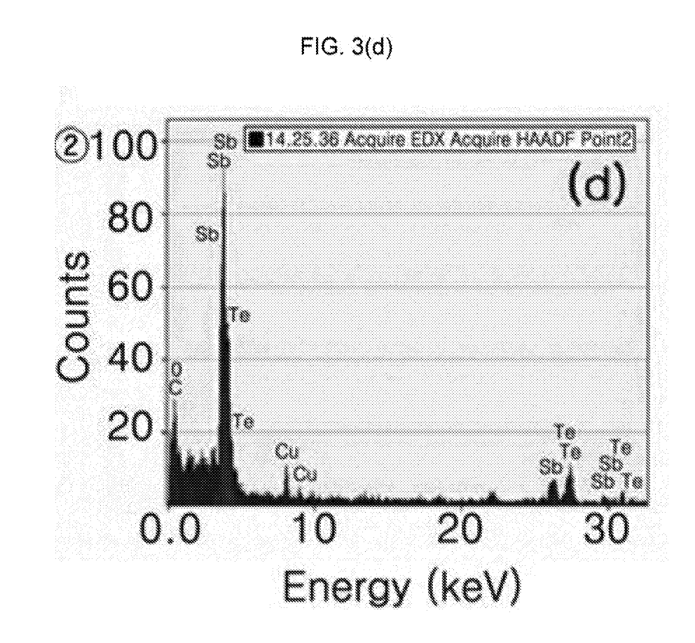

FIG. 3(a) to 3(d) show electron microscopic images for the interface in the thermoelectric composite material according to Example 1 ((a) 5,000 times magnification and (b) 20,000 times magnification), and graphs showing an energy dispersive X-ray spectroscopy of the composition for the thermoelectric composite material according to Example 1 ((c) Ag₂Te part indicated by red square in (a) and Sb₂Te₃ part indicated by dark area in (b)). Referring to FIGS. 3(a) and 3(b), the dark area (dark gray or black portion) indicates Sb₂Te₃ matrix, and the light area (white or light gray portion) indicates Ag₂Te particles, where the interface formed between the Sb₂Te₃ matrix and the Ag₂Te particles was found. In addition, referring to FIGS. 3(c) and 3(d), the phase separation between Sb₂Te₃ and Ag₂Te was observed.

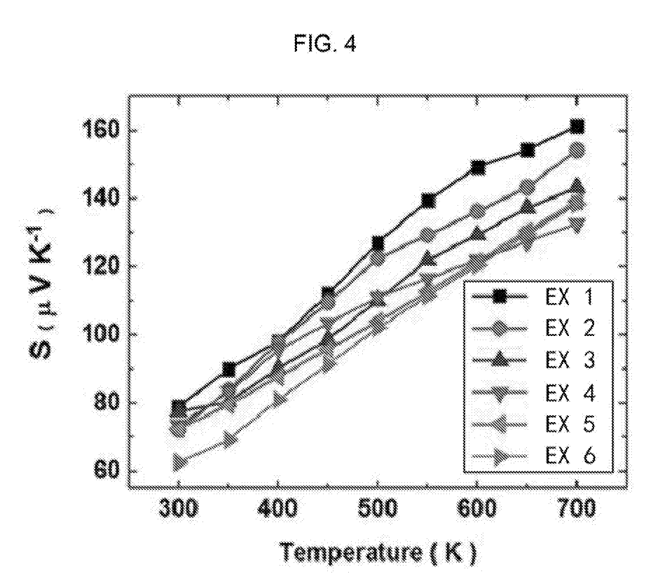

FIG. 4 is a graph showing a Seebeck coefficient versus temperatures of the thermoelectric composite material according to Examples 1 to 6. Referring to FIG. 4, it was found that the thermoelectric composite material according to Examples 1 to 6 functions as a p-type thermoelectric material, since the Seebeck coefficient was increased with the temperature increase. In addition, the Seebeck coefficient was found to show a tendency to increase with the content increase in Ag₂Te relative to Sb₂Te₃.

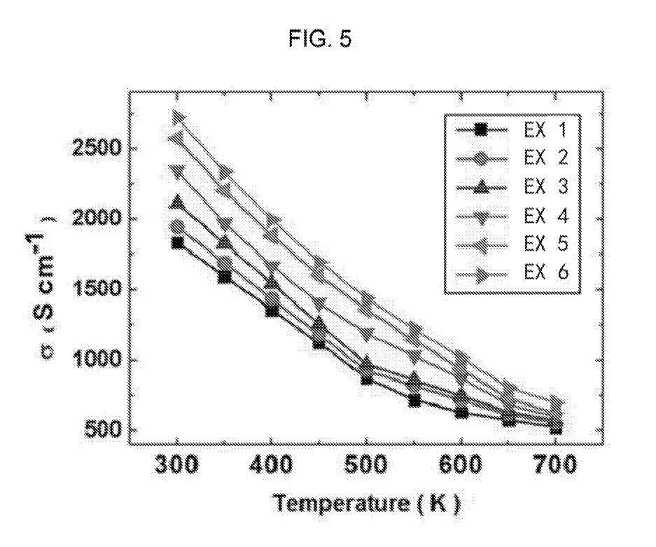

FIG. 5 is a graph showing an electrical conductivity versus temperatures of the thermoelectric composite material according to Examples 1 to 6. Referring to FIG. 5, it was found that the thermoelectric composite material according to Examples 1 to 6 functions as a degenerated semiconductor or a semimetal, since the electrical conductivity was decreased with the temperature increase. In addition, the electrical conductivity was found to show a tendency to increase with the content decrease in Ag₂Te relative to Sb₂Te₃.

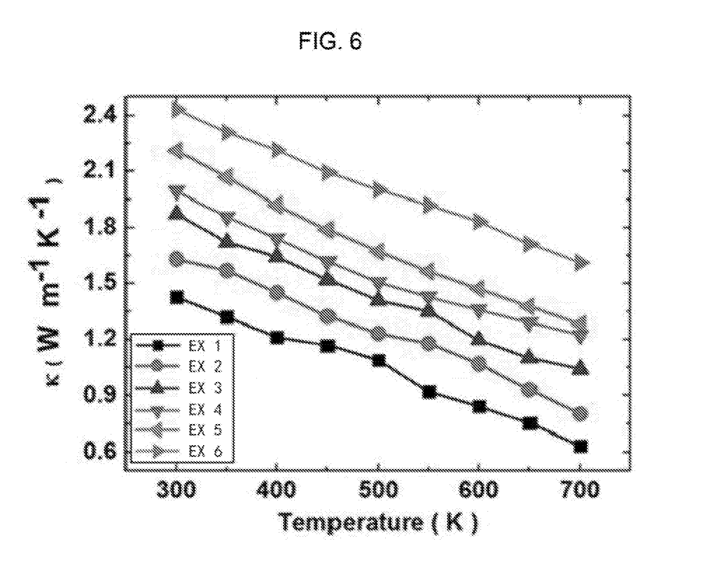

FIG. 6 is a graph showing a thermal conductivity versus temperatures of the thermoelectric composite material according to Examples 1 to 6. Referring to FIG. 6, it was found that an acoustic phonon is a main factor of heat transfer, since in the thermoelectric composite material according to Examples 1 to 6, the thermal conductivity was decreased with the temperature increase. The electrical conductivity was found to show a tendency to decrease with the content increase in Ag₂Te relative to Sb₂Te₃. In particular, in the case of the thermoelectric composite material according to Example 1, the thermal conductivity was found to decrease about 30% as compared to Sb₂Te₃ compound having thermal conductivity of about 1.8 W/Mk at 300K.

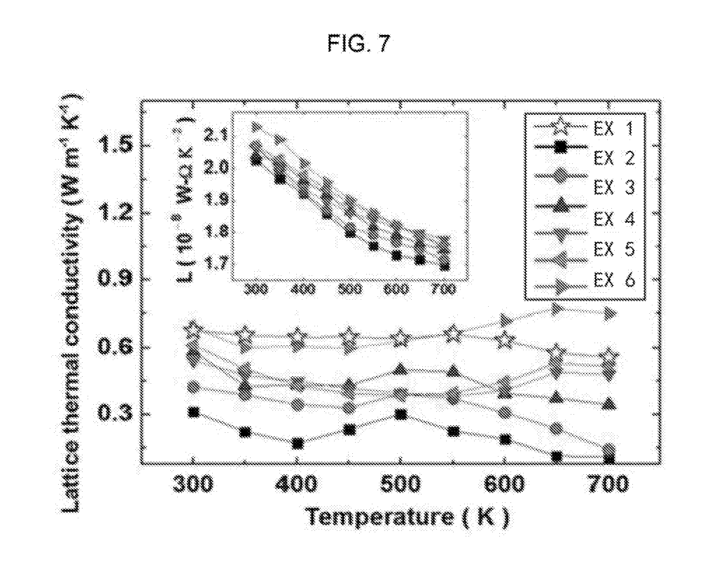

FIG. 7 is a graph showing a lattice thermal conductivity versus temperatures of the thermoelectric composite material according to Examples 1 to 6. The thermal conductivity due to the electrons was calculated from Lorentz number L by Wiedemann-Franz's law (i.e., κₑ=LσT). The lattice thermal conductivity was calculated by subtracting the thermal conductivity due to the electrons from the thermal conductivity. Referring to FIG. 7, it was found that the lattice thermal conductivity of the thermoelectric composite material according to Examples 1 to 6 was as significantly low as about 0.3 to 0.6 W/mK.

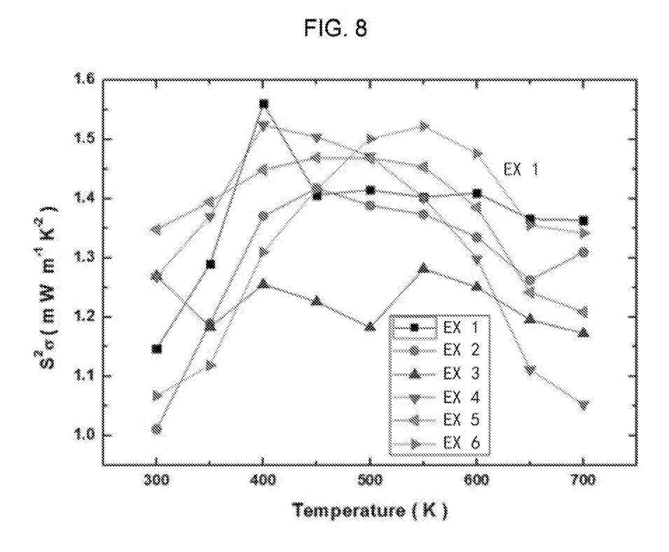

FIG. 8 is a graph showing a power factor (S²σ) versus temperatures of the thermoelectric composite material according to Examples 1 to 6. Referring to FIG. 8, the thermoelectric composite material according to Examples 1 to 6 was found to show a high level of power factor over a wide area depending on the temperature.

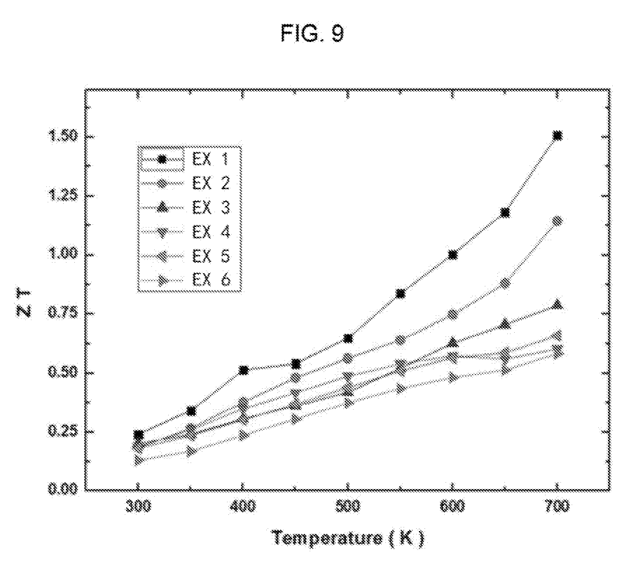

FIG. 9 is a graph showing a dimensionless performance index (ZT) value versus temperatures of the thermoelectric composite material according to Examples 1 to 6. Referring to FIG. 9, the thermoelectric composite material according to Examples 1 to 6 was found to show a tendency that the dimensionless performance index (ZT) values increases with the content increase in Ag₂Te relative to Sb₂Te₃. Further, the thermoelectric composite material according to Example 1 was found to show a very high value of dimensionless performance index of about 1.5 at 700K.

Description of the invention described above are for illustrative purposes, One of ordinary skill in the art can understand that it is possible to easily modified in other specific forms without changing the technical spirit or essential features of the invention will. Thus, embodiments described above are illustrative and in any way should be understood as non-limiting.

What is claimed is:

1. A thermoelectric composite material comprising:
a Sb—Te-based matrix; and
Ag—Te-based particles dispersed in the matrix phase,
wherein an interface is formed between the matrix and the particles.

2. The thermoelectric composite material of claim 1, wherein Sb in the matrix is doped with at least one element selected from the group consisting of Te, Sn and Pb, or Te in the matrix is doped with at least one element selected from the group consisting of Se, S, I, Br and Cl.

3. The thermoelectric composite material of claim 1, wherein Ag in the particles is doped with at least one element selected from the group consisting of Zn, Cu, Ni, Co, Fe, Cd, Pd, Rh, Ru, Au and Pt, or Te in the particles is doped with at least one element selected from the group consisting of Se, S, I, Br and Cl.

4. The thermoelectric composite material of claim 1, wherein the particles have a melting point in the range of 600 to 1,000° C.

5. The thermoelectric composite material of claim 1, wherein the particles have a diameter in the range of 20 nm to 2 μm.

6. The thermoelectric composite material of claim 1, wherein the particles are conglomerated to form a cluster, or the particles are in discrete form.

7. The thermoelectric composite material of claim 1, wherein the weight ratio of the matrix to the particles is 1:1 to 20:1.

8. The thermoelectric composite material of claim 1, which is a bulk phase.

9. The thermoelectric composite material of claim 1, which has a Seebeck coefficient of 120 μV/K or more at 700K.

10. The thermoelectric composite material of claim 1, which has an electric conductivity of 500 S/cm or more.

11. The thermoelectric composite material of claim 1, which has a thermal conductivity of 1.8 W/mK or less.

12. The thermoelectric composite material of claim 1, which has a density corresponding to 70% to 100% of the theoretical density.

13. A method for producing the thermoelectric composite material according to claim 1, comprising:
mixing a Sb—Te-based compound and an Ag—Te-based compound; and
precipitating the Ag—Te-based compound from the mixture.

14. A method for producing the thermoelectric composite material according to claim 1, comprising:
melting a raw material comprising the elements Sb, Ag and Te; and
inducing a phase separation of the melt.
